(19) United States
(12) Patent Application Publication
(10) Pub. No.: US 2025/0309634 A1
(43) Pub. Date: Oct. 2, 2025

(54) CONTROL DEVICE, ELECTRIC APPARATUS, AND CONTROL METHOD OF ELECTRIC APPARATUS

(71) Applicants: KABUSHIKI KAISHA TOSHIBA, Tokyo (JP); Toshiba Electronic Devices & Storage Corporation, Tokyo (JP)

(72) Inventor: Motomichi Shibano, Atsugi Kanagawa (JP)

(73) Assignees: KABUSHIKI KAISHA TOSHIBA, Tokyo (JP); Toshiba Electronic Devices & Storage Corporation, Tokyo (JP)

(21) Appl. No.: 18/824,263

(22) Filed: Sep. 4, 2024

(30) Foreign Application Priority Data
Apr. 2, 2024 (JP) 2024-059555

(51) Int. Cl. H02H 7/08; G01R 23/12; G01R 31/34

(52) U.S. Cl. CPC H02H 7/0833; G01R 23/12; G01R 31/343

(57) ABSTRACT

According to one embodiment, a control device includes: a control circuitry configured to control an electric motor; and a failure sensing circuitry configured to sense a failure of the electric motor, wherein the failure sensing circuitry executes frequency analysis concerning an electric signal for driving the electric motor, calculates a phase of the electric signal, calculates a phase difference between a phase of a fundamental wave of a power supply frequency of the electric signal and the calculated phase of the electric signal, extracts a first signal indicating an outflow component from the electric motor based on a calculation result of the phase difference, extracts a second signal indicating an inflow component to the electric motor based on the calculation result of the phase difference, and senses the failure based on the first signal.

### CROSS-REFERENCE TO RELATED APPLICATIONS

This application is based upon and claims the benefit of priority from prior Japanese Patent Application No. 2024-059555, filed Apr. 2, 2024, the entire contents of which are incorporated herein by reference.

### FIELD

Embodiments described herein relate generally to a control device, an electric apparatus, and a control method of an electric apparatus.

### BACKGROUND

A device configured to detect a failure of an electric motor is incorporated in an apparatus including the electric motor which is driven by an AC power supply.

### BRIEF DESCRIPTION OF THE DRAWINGS

FIG. 1 is a circuit diagram showing an arrangement example of an electric apparatus including a control device according to the first embodiment.

FIG. 2 is a block diagram showing an arrangement example of a failure sensing unit in the control device according to the first embodiment.

FIG. 3 is a view showing experimental results concerning the control device according to the first embodiment.

FIG. 4 is a view showing experimental results concerning the control device according to the first embodiment.

FIG. 5 is a flowchart showing an operation example of the control device according to the first embodiment.

FIG. 6 is a view showing an arrangement example of an electric apparatus including a control device according to the second embodiment.

FIG. 7 is a view showing experimental results concerning the control device according to the second embodiment.

FIG. 8 is a view showing experimental results concerning the control device according to the second embodiment.

FIG. 9 is a view showing an arrangement example of an electric apparatus including a control device according to the third embodiment.

FIG. 10 is a view showing a modification of the control device according to the embodiment.

### DETAILED DESCRIPTION

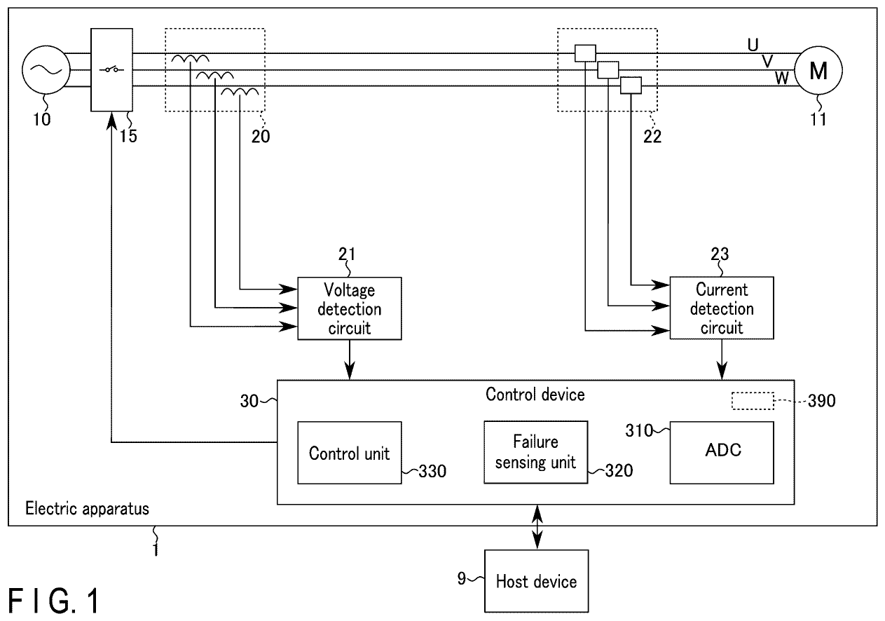

With reference to FIGS. 1, 2, 3, 4, 5, 6, 7, 8, 9, and 10, a control device, an electric apparatus, and a control method of the electric apparatus according to each embodiment will be described. In the following description, the same reference numerals denote elements having the same functions and arrangements. In the following embodiment, when constituent elements (for example, circuits, interconnections, and various voltages and signals) having reference numerals with numerals/alphabetical letters at the end for distinction need not be distinguished from each other, descriptions (reference numerals) from which numerals/alphabetical letters at the end are omitted are used.

In general, according to one embodiment, a control device includes: a control circuitry configured to control an electric motor; and a failure sensing circuitry configured to sense a failure of the electric motor, wherein the failure sensing circuitry executes frequency analysis concerning an electric signal for driving the electric motor, calculates a phase of the electric signal, calculates a phase difference between a phase of a fundamental wave of a power supply frequency of the electric signal and the calculated phase of the electric signal, extracts a first signal indicating an outflow component from the electric motor based on a calculation result of the phase difference, extracts a second signal indicating an inflow component to the electric motor based on the calculation result of the phase difference, and senses the failure based on the first signal.

### EMBODIMENTS

### (1) First Embodiment

With reference to FIGS. 1, 2, 3, 4, and 5, a control device and an electric apparatus according to the first embodiment will be described.

### (a) Arrangement Example

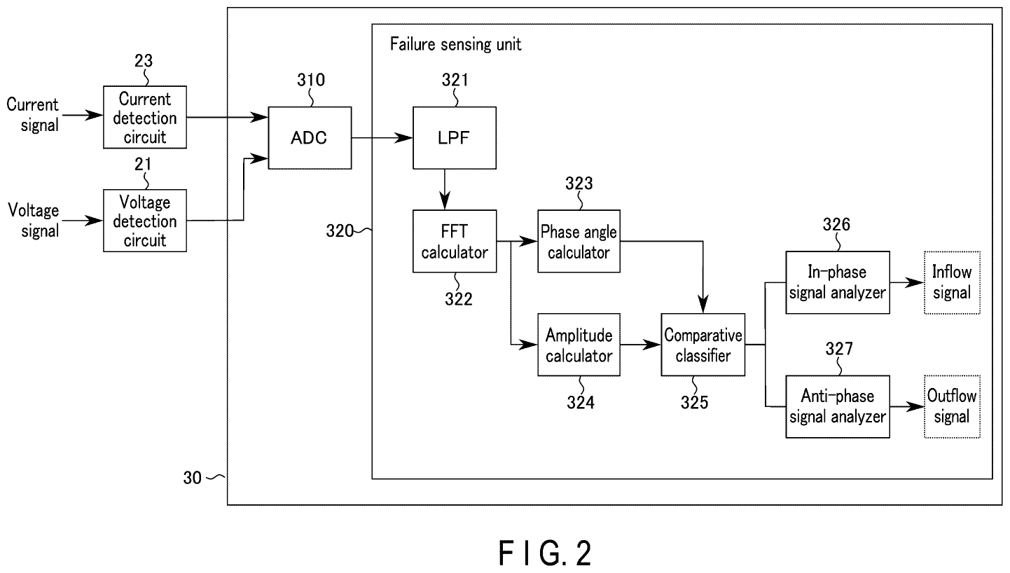

With reference to FIGS. 1 and 2, an arrangement example of the control device and an arrangement example of the electric apparatus according to this embodiment will be described.

FIG. 1 is a circuit diagram showing an arrangement example of an electric apparatus 1 including a control device 30 according to this embodiment. In FIG. 1, the electric apparatus 1 according to this embodiment is configured to control a three-phase induction electric motor (induction motor) using a three-phase AC power supply.

As shown in FIG. 1, the electric apparatus 1 according to this embodiment includes an AC power supply 10, a motor (electric motor) 11, a switch (cut-off circuit) 15, a voltage sensor circuit 20, a voltage detection circuit 21, a current sensor circuit 22, a current detection circuit 23, the control device 30, and the like.

The AC power supply 10 is connected to the motor 11 by three-phase connection. The AC power supply 10 supplies, to the motor 11, a three-phase AC voltage (and AC current) including a U phase, a V phase, and a W phase. Note that the AC power supply 10 may be a constituent element outside the electric apparatus 1.

The motor 11 is driven by an electric signal from the AC power supply 10. The motor 11 is driven by receiving a voltage (and current) including the U phase, V phase, and W phase via the three-phase connection. The motor 11 generates a mechanical energy by the AC voltage from the AC power supply 10. For example, the output shaft of the motor 11 is connected to a load device (not shown) and a driving device (not shown).

The switch 15 is provided between the AC power supply 10 and the motor 11. The switch 15 controls voltage supply from the AC power supply 10 to the motor 11 under the control of the control device 30. For example, if a failure of the motor 11 is detected, the switch 15 cuts off the voltage supply from the AC power supply 10 to the motor 11.

The voltage sensor circuit 20 is connected to the three-phase connection. The voltage sensor circuit 20 senses the voltage supplied to each phase wiring forming the three-phase connection. The voltage sensor circuit 20 includes a voltage sensor such as a voltage transformer (VT) to detect each phase voltage.

The voltage detection circuit 21 is connected to the voltage sensor circuit 20. The voltage detection circuit 21 receives a voltage signal corresponding to the sense result of each phase voltage by the voltage sensor circuit 20. Based on the sense result of the voltage sensor circuit 20, the voltage detection circuit 21 detects the state of each phase voltage in the three-phase connection. The voltage detection circuit 21 has a function of converting the voltage signal from the voltage sensor circuit 20 into a signal corresponding to the input voltage of an analog digital converter (ADC) 310 of the control device 30 to be described later.

The current sensor circuit 22 is connected to the three-phase connection. The current sensor circuit 22 senses the current (phase current) flowing through each phase wiring forming the three-phase connection. The current sensor circuit 22 includes a current sensor such as a current transformer (CT) to detect the phase current.

The current detection circuit 23 is connected to the current sensor circuit 22. The current detection circuit 23 receives a current signal corresponding to the sense result of each phase current by the current sensor circuit 22. Based on the sense result of the current sensor circuit 22, the current detection circuit 23 detects the state of each phase current in the three-phase connection. To apply the current signal from the current sensor circuit 22 to the input of the ADC 310 to be described later, the current detection circuit 23 has a function of performing voltage conversion or impedance matching.

The control device 30 controls the internal operation of the electric apparatus 1. In the electric apparatus 1 according to this embodiment, the control device 30 includes the ADC 310, a failure sensing unit (failure sensing circuitry) 320, a control unit (control circuitry) 330, and the like.

The ADC 310 converts various analog signals (analog values) detected in the electric apparatus 1 into digital signals (digital values). For example, the ADC 310 converts a signal from the voltage detection circuit 21 and a signal from the current detection circuit 23 into digital signals.

The failure sensing unit (to be also referred to as a failure sensing circuit) 320 senses, based on various signals detected in the electric apparatus 1, a fault in the electric apparatus 1 such as a failure of the motor 11 or a malfunction of the AC power supply 10.

The control unit (to be also referred to as a control circuit) 330 monitors the operation state of each constituent element in the electric apparatus 1, and controls the operation of each constituent element. The control unit 330 can control the function and processing of the failure sensing unit 320. The control unit 330 is, for example, a processor.

Note that the control device 30 can further include a memory 390. The memory 390 stores various data. For example, the memory 390 can store data of voltage and current sense results (for example, data of the electric signal), and programs (software and application) for controlling the electric motor.

The electric apparatus 1 according to this embodiment is driven by the three-phase AC power supply 10. The electric apparatus 1 controls the rotation of the motor 11 by the control device 30 while sensing the voltage value and the current value generated by the three-phase AC power supply 10.

For example, if a failure including an overcurrent, a short circuit, an earth fault, and the like occurs in the motor 11, the electric apparatus 1 cuts off the AC power supply 10 by the switch 15 based on an instruction from the control device 30. For example, if an abnormality including phase interruption, imbalance, dip, swell, and the like occurs in the AC power supply 10, the electric apparatus 1 protects the motor 11 by a cut-off operation of the switch 15 based on an instruction from the control device 30.

The electric apparatus 1 according to this embodiment communicates with a host device 9 such as a PLC (Programmable Logic Controller). The host device 9 communicates with the control devices 30 of a plurality of electric apparatuses 1. The host device 9 monitors the operating state of the electric apparatus 1 based on the result of communication. For example, the host device 9 monitors periodic power consumption, the state signal obtained in real time from the failure sensing unit 320, and the like. With this, the host device 9 grasps the state of the motor 11 and the state of a load device (not shown) in the electric apparatus 1.

In this embodiment, the control device 30 senses a failure on the motor 11 side and a failure on the power supply 10 side by analysis processing of the failure sensing unit 320.

FIG. 2 shows an arrangement example of the failure sensing unit 320 of the control device 30 in the electric apparatus 1 according to this embodiment. Note that FIG. 2 shows an example of the arrangement of a signal calculator for the electric signals (voltage signal and current signal) of one phase of the three-phase system. Substantially the same calculation is executed for the current signals (current values) and voltage signals (voltage values) of the other phases.

The failure sensing unit 320 executes various calculation processing operations. The calculation processing by the failure sensing unit 320 includes frequency analysis of the electric signal between the AC power supply 10 and the motor 11. To sense the phase difference of the detected electric signal, the failure sensing unit 320 has various configurations (functional blocks) for distinguishing the phase information of the electric signal.

The failure sensing unit 320 includes one or more calculators (processors) each formed by a microcontroller unit (MCU) or an ASIC (application specific integrated circuit) in the control device 30. The failure sensing unit 320 can use data and programs in the memory 390.

As shown in FIG. 2, the failure sensing unit 320 includes an LPF (low pass filer) 321, an FFT (fast Fourier transform) calculator 322, a phase angle calculator 323, an amplitude calculator 324, a comparative classifier 325, an in-phase signal analyzer 326, an anti-phase signal analyzer 327, and the like.

The voltage detection circuit 21 and the current detection circuit 23 are connected to the control device 30. The voltage detection circuit 21 detects a voltage signal (analog signal) based on the sense result of the voltage sensor circuit 20. The voltage detection circuit 21 transmits the voltage signal corresponding to the detection result to the ADC 310 of the control device 30. The current detection circuit 23 detects a current signal (analog signal) based on the sense result of the current sensor circuit 22. The current detection circuit 23 transmits the current signal corresponding to the detection result to the ADC 310 of the control device 30.

In the control device 30, the ADC 310 analog-digital converts (AD-converts) the signal from the voltage detection circuit 21 and the signal from the current detection circuit 23. The ADC 310 transmits the digital signals obtained by AD-conversion to the LPF 321 in the failure sensing unit 320.

The LPF 321 allows the signal having a frequency equal to or lower than a cut-off frequency in the digital signal from the ADC 310 to pass therethrough. The LPF 321 transmits the signal having undergone filtering processing (signal having undergone LPF processing) to the FFT calculator 322. The LPF 321 limits, by the LPF processing, the band of the digital signal to the signal band for monitoring the state of the motor 11 (the state of the electric apparatus 1). With this, the failure sensing unit 320 can block, for example, harmonic noise and disturbance noise included in the signal caused by the power supply 10 in the electric signals indicating the current and voltage detection results.

Note that, in order to improve the SN ratio of the signal, filter processing on the digital signal from the ADC 310 can employ LPF processing as decimation filter processing (averaging and down sampling processing).

The FFT calculator 322 performs FFT operation on the signal from the LPF 321. The FFT calculation is signal processing of performing Fourier transform at high speed. The FFT calculator 322 performs fast Fourier transform processing on the signal from the LPF 321. With this, the complex function concerning the electric signal can be obtained. The FFT calculator 322 transmits the signal indicating the result of FFT calculation to the phase angle calculator 323 and the amplitude calculator 324. The FFT calculation result by the FFT calculator 322 is divided and extracted as phase angle component information and amplitude component information in the electric signal. The FFT calculator 322 transmits the phase angle information based on the result of FFT calculation to the phase angle calculator 323. The FFT calculator 322 supplies the amplitude component information based on the result of FFT calculation to the amplitude calculator 324.

In the processing by the FFT calculator 322, the calculation load changes depending on the number of input samples. Since the signal band in the induction motor is up to about 1 kHz, the FFT calculator 322 often performs calculation using 1024 to 2048 samples. Note that, in order to clearly capture the peak of the sideband wave generated by a deterioration of the bearing of the motor 11, the number of samples and signal band of the FFT calculation may be adjusted to set the frequency resolution to 1 Hz or less.

The FFT calculator 322 can be implemented by implementation by software or implementation by a hardware accelerator.

The phase angle calculator 323 calculates the phase angle (phase) of the electric signal. The phase angle calculator 323 transmits the calculated phase angle to the comparative classifier 325.

The amplitude calculator 324 calculates the amplitude of the electric signal. The amplitude calculator 324 transmits the calculated amplitude to the comparative classifier 325.

The comparative classifier 325 receives the phase angle calculation result by the phase angle calculator 323 and the amplitude calculation result by the amplitude calculator 324. The comparative classifier 325 compares the phase angle of the fundamental wave of the power supply frequency of the electric signal (to be simply referred to as the fundamental wave hereinafter) with the phase angle of each electric signal. The comparative classifier 325 classifies a plurality of electric signals in accordance with the magnitude of the compared phase angle. The comparative classifier 325 compares the amplitude of the fundamental wave of the power supply frequency of the electric signal with the amplitude of each electric signal. The comparative classifier 325 classifies a plurality of electric signals in accordance with the magnitude of the compared amplitude.

The comparative classifier 325 classifies, based on the phase angle component information of the result of FFT calculation, an in-phase signal (to be also referred to as an inflow signal) having an in-phase phase difference from the phase of the fundamental wave of the electric signal corresponding to the power supply frequency, and an anti-phase signal (to be also referred to as an outflow signal) having an anti-phase phase difference from the phase of the fundamental wave of the electric signal corresponding to the power supply frequency. Based on the classification result of the electric signal according to the magnitude of the phase difference, the comparative classifier 325 transmits the classified signal to one of the in-phase signal analyzer 326 and the anti-phase signal analyzer 327.

For example, the comparative classifier 325 calculates and compares the phase difference between the phase of the fundamental wave of the voltage signal and the phase of the current signal (or voltage signal) with the phase of the fundamental wave of the voltage signal in the power supply frequency as a reference. Based on the comparison result, the comparative classifier 325 classifies the electric signal.

Based on the classification result of the comparative classifier 325, the in-phase signal analyzer 326 analyzes the electric signal (inflow signal or in-phase signal) which is in-phase with the phase of the fundamental wave of the electric signal (voltage signal here).

The inflow signal is a signal (frequency component) having a phase difference smaller than ±90°. More specifically, the inflow signal is a signal having, of a phase difference within a range of 0° to ±180°, a phase difference within one of a range of 0° to ±90° and a range of 0° to −90° with respect to the phase of the fundamental wave. The inflow signal is a signal indicating the inflow component to the motor 11. The inflow component (frequency component) is a component representing the characteristic of the electric signal of the power supply 10, and a change in the inflow component in the inflow signal represents a change in the state of the power supply 10. That is, the inflow signal is a signal derived from the power supply 10.

Based on the classification result of the comparative classifier 325, the anti-phase signal analyzer 327 analyzes the electric signal (outflow signal or anti-phase signal) having the phase opposite to the phase of the electric signal (voltage signal here).

The outflow signal is a signal (frequency component) having a phase difference of ±90° (inclusive) to 180° (inclusive). More specifically, the outflow signal is a signal having, of a phase difference within a range of 0° to ±180°, a phase difference within one of a range of +90° to +180° and a range of −90° to −180°. The outflow signal is a signal indicating the outflow component from the motor 11. The outflow component (frequency component) is, for example, a component generated due to a change of the mutual inductance (transinductance) of the rotor of the motor 11 and caused by a mechanical vibration. If the vibration increases due to a deterioration of the constituent element of the motor 11 such as the bearing, the outflow component signal increases. That is, the outflow signal is a signal derived from the motor 11, and can serve as a signal for monitoring the failure state of the motor 11.

The in-phase signal analyzer 326 generates a control signal based on the inflow signal analysis result. The anti-phase signal analyzer 327 generates a control signal based on the outflow signal analysis result. For example, the control unit 330 controls the operations of the motor 11 and the electric apparatus 1 based on the control signal from the in-phase signal analyzer 326 and the control signal from the anti-phase signal analyzer 327. The failure sensing unit 320 may directly control the operations of the motor 11 and the electric apparatus 1 in accordance with the control signals based on the analysis results.

The electric apparatus 1 according to this embodiment can grasp the failure state of the motor 11 by analysis of the outflow signal by the failure sensing unit 320. The electric apparatus 1 according to this embodiment can grasp the failure state of the AC power supply 10 (and system) by analysis of the inflow signal by the failure sensing unit 320.

Note that the failure sensing unit 320 may include a calculator independent of the control device 30 as a circuit or device including the above-described function of the failure sensing unit 320. In this case, the failure sensing unit 320 can execute various calculation processing operations for sensing a failure of the electric apparatus 1 independent of normal control of the electric apparatus 1 by the control device 30.

### (b) Experiments and Verification

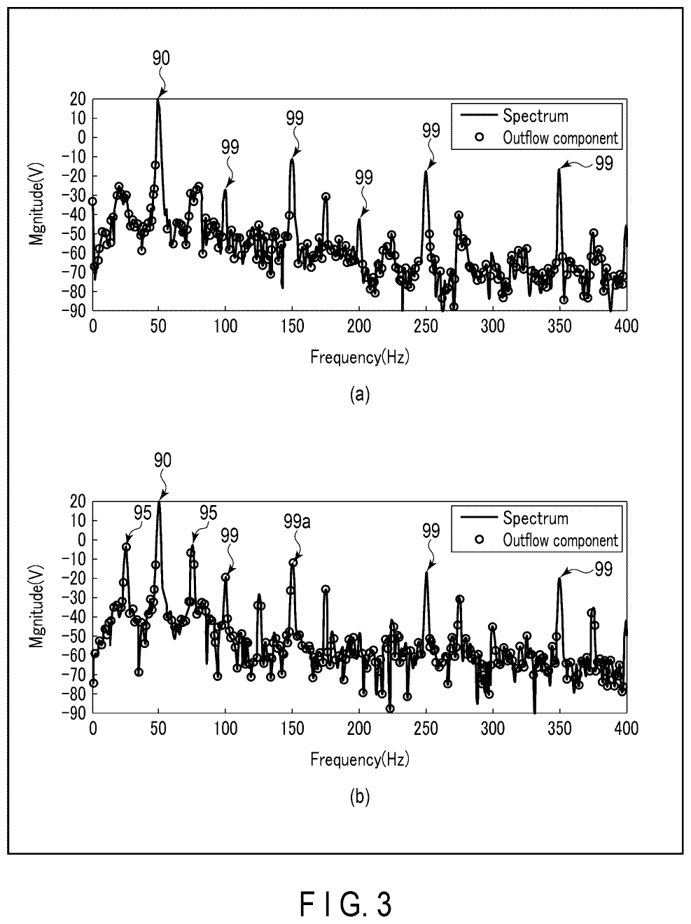

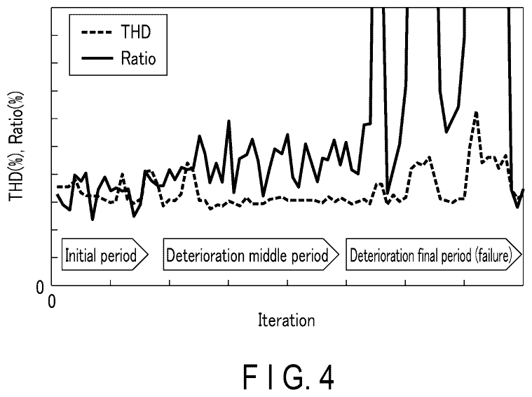

With reference to FIGS. 3 and 4, experimental results of failure sensing by the failure sensing unit 320 in the electric apparatus 1 according to this embodiment will be described.

FIG. 3 is a graph showing experimental results of the electric apparatus 1 according to this embodiment. FIG. 3 shows, as an example of experiment, an example in which an experiment of promoting the failure of the bearing of the induction motor was conducted, and the inflow signal and the outflow signal were compared in frequency analysis.

(a) of FIG. 3 shows the motor current spectrum in the initial state of the deterioration of the bearing of the induction motor. In (a) of FIG. 3, the abscissa of the graph corresponds to the frequency, and the ordinate of the graph corresponds to the magnitude of the signal.

In (a) of FIG. 3, a peak 90 of 50 Hz corresponds to the fundamental wave of the electric signal represented by the motor current spectrum. Note that the second and subsequent harmonic peaks after the fundamental wave 90 is not an outflow component.

Here, assume that the phase difference of the phase current relative to the power supply voltage is small. Based on this assumption, the inflow component (inflow signal) and the outflow component (outflow signal) are distinguished in accordance with the phase difference of the current signal relative to the fundamental wave (50 Hz) of the power supply voltage (voltage signal or current signal).

As shown in (a) of FIG. 3, in the waveform of the electric signal in the initial state of the deterioration (in the substantially normal state of the motor 11), the phase change of a harmonic component 99 of the power supply is small with respect to the fundamental wave 90 of 50 Hz in the voltage signal. Thus, it can be found that this is a component which is in-phase with the fundamental wave.

Each circle plot in (a) (and (b)) of FIG. 3 indicates the outflow component signal (outflow signal). The outflow signals represent, in addition to the harmonic of the power supply frequency, a signal corresponding to a mechanical vibration and a signal having an anti-phase component due to an inductive fluctuation caused by other reasons. In the initial state of the deterioration of the electric apparatus 1, most of the outflow component signals are signals corresponding to noise.

(b) of FIG. 3 shows the motor current spectrum in the final state of the deterioration of the bearing of the induction motor. In (b) of FIG. 3, the abscissa of the graph corresponds to the frequency, and the ordinate of the graph corresponds to the magnitude of the signal.

In (b) of FIG. 3, each sideband wave 95 appears in a portion shifted from the fundamental wave 90 of the voltage signal by a rotational frequency (25 Hz here).

Among the harmonic components 99 of the power supply frequency, a third harmonic component 99a was modulated by vibration and turned to an outflow component.

In general, the final state of the deterioration is a state in which the deterioration of the bearing of the induction motor has advanced to the level where the motor needs replacing.

The component of each sideband wave 95 caused by the vibration of the bearing, which is a mechanical failure signal, is sensed as the outflow signal. In analysis of the motor current spectrum, normally, if the difference of the peak level of the sideband wave 95 is 40 dB or less, it is determined that the induction motor is in the failure state.

In (b) of FIG. 3, the difference between the peak level of the fundamental wave 90 of the power supply frequency and the peak level of the sideband wave 95 in each of the initial state and the final state of the electric apparatus 1 is about 20 dB to 30 dB. From this, it can be recognized that the deterioration of the bearing of the induction motor is in progress.

In the electric apparatus 1 according to this embodiment, the failure sensing unit 320 monitors the failure state of the bearing of the motor 11 by using the increase of the peak value of the sideband wave 95 as a guideline.

In this embodiment, among the harmonic components 99 of the power supply frequency, the third harmonic component 99a becomes the outflow component. Thus, it can be estimated that a phase difference occurred between the fundamental wave of the voltage signal and the measured current signal due to electromagnetic influence.

In the above-described experimental results, it is shown that the failure signal due to the mechanical vibration component or the electrical failure signal can be distinguished as the outflow component signal.

FIG. 4 shows the results obtained by continuously monitoring the deterioration state of the bearing of the motor from the initial state in the electric apparatus 1 according to this embodiment. In FIG. 4, the abscissa of the graph represents the number of times of measurement at an interval of a certain unit time, which corresponds to the elapsed time. In FIG. 4, the ordinate of the graph corresponds to THD (total harmonic distortion) and Ratio. For example, each of the THD value and Ratio value is expressed by percentage (%).

THD is a value evaluating the motor current spectrum by the degree of harmonic distortion. Ratio indicates the ratio of the total sum of amplitudes of outflow components to the RMS value (the total spectrum amplitude) (that is, the outflow component total sum value/RMS value). Ratio concerning the amplitudes of the outflow components is calculated with the RMS value as the denominator. With this, the magnitude of the outflow component can be normalized with respect to the amplitude variation.

In general, it is understood that, as the harmonic distortion rate increases, the failure state of the electric motor advances. Note that not all the cases where a high harmonic distortion rate is detected correspond to the failure of the electric motor.

THD shows little change along with the deterioration of the bearing. Thus, THD alone is not suitable for monitoring the failure state.

To the contrary, as shown in FIG. 4, the ratio of the outflow components to the RMS tends to increase along with the deterioration of the bearing.

It can be seen from FIG. 4 that, in analysis of the outflow component according to this embodiment, the deterioration state of the motor bearing is well reflected on the ratio of the outflow components.

### (c) Operation Example

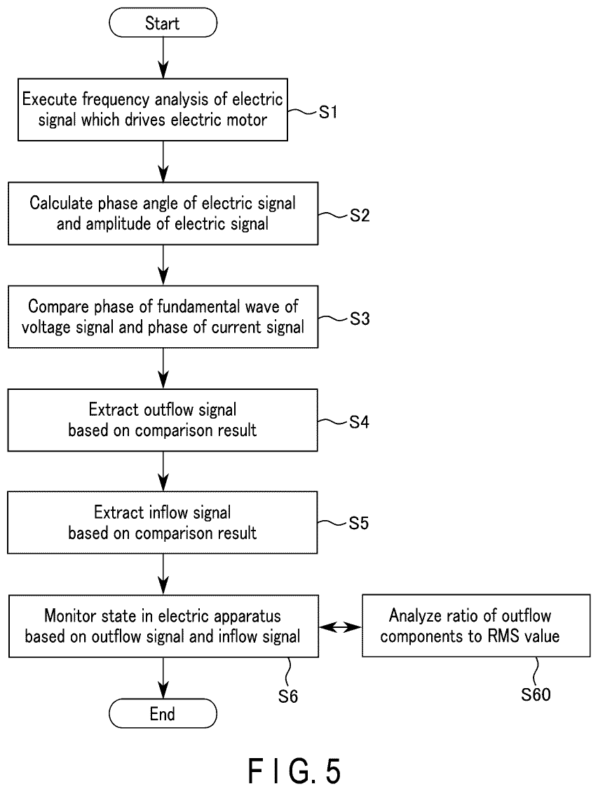

With reference to FIG. 5, an operation example of the electric apparatus 1 according to this embodiment will be described. The operation of the electric apparatus 1 according to this embodiment is related to the control method of the electric apparatus 1.

FIG. 5 is a flowchart showing an operation example of the electric apparatus 1 according to this embodiment.

As shown in FIG. 5, during the operation of the electric apparatus 1 according to this embodiment, the control device 30 executes frequency analysis of the electric signal (voltage signal and current signal) which drives the motor 11 (step S1).

The control device 30 receives signals from the voltage detection circuit 21 and the current detection circuit 23. The control device 30 converts the signals from the voltage detection circuit 21 and the current detection circuit 23 into digital signals by the ADC 310. The ADC 310 transmits the converted digital signals to the LPF 321. The LPF 321 executes LPF processing on the digital signals. The FFT calculator 322 executes FFT calculation on the LPF-processed digital signals.

The control device 30 calculates the phase angle and amplitude of the electric signal having undergone various processing operations by the frequency analysis (step S2).

The control device 30 compares the calculated phase angle of the electric signal (for example, current signal) with the phase angle of the fundamental wave of the power supply frequency of the electric signal (for example, voltage signal) (step S3).

The control device 30 extracts and analyzes the outflow signal (anti-phase signal) indicating the outflow component from the motor 11 (step S4). The outflow signal is a signal where the phase difference between the phase angle of the current signal and the phase angle of the fundamental wave of the voltage signal is ±90° (inclusive) to 180° (inclusive).

The control device 30 extracts and analyzes the inflow signal (in-phase signal) indicating the inflow component to the motor 11 (step S5). The inflow signal is a signal where the phase difference between the phase angle of the current signal and the phase angle of the fundamental wave of the voltage signal is smaller than ±90°.

Based on the analysis results of the outflow signal and the inflow signal, the control device 30 monitors the state in the electric apparatus 1 (Step S6). The control device 30 senses a failure of the motor 11 based on the outflow signal. The control device 30 senses a malfunction on the AC power supply 10 side based on the inflow signal.

For example, the control device 30 calculates and analyzes the ratio of the total sum value of the inflow components to the RMS value (step S60). For example, the control device 30 analyzes the sideband wave of the fundamental wave of the current signal (or the voltage signal). For example, the control device 30 analyzes the harmonic (for example, the third harmonic component) of the fundamental wave. Based on these analysis results, the control device 30 senses a failure of the motor 11 and a malfunction of the AC power supply 10.

With the process described above, the electric apparatus 1 according to this embodiment ends the operation for monitoring in the electric apparatus 1 by the control device 30. Based on the monitoring result of the electric apparatus 1, the control device 30 controls the operation of the electric apparatus 1.

### (d) Summary

As has been described above, the electric apparatus 1 according to this embodiment acquires the signal indicating the outflow component serving as a guideline for sensing a failure of the motor 11 in the electric apparatus 1, and the signal indicating the inflow component used to grasp the state of the power supply 10.

With this, the electric apparatus 1 according to this embodiment can obtain the feature amount that enables accurate grasp of the failure state of each of the motor main body, the load device of the motor, and the driving device. In addition, the electric apparatus 1 according to this embodiment can distinguish the influence of the failure on the power supply side from the influence of the failure occurring on the motor side.

As a result, the electric apparatus 1 according to this embodiment can implement a stable operation of the electric apparatus.

### (2) Second Embodiment

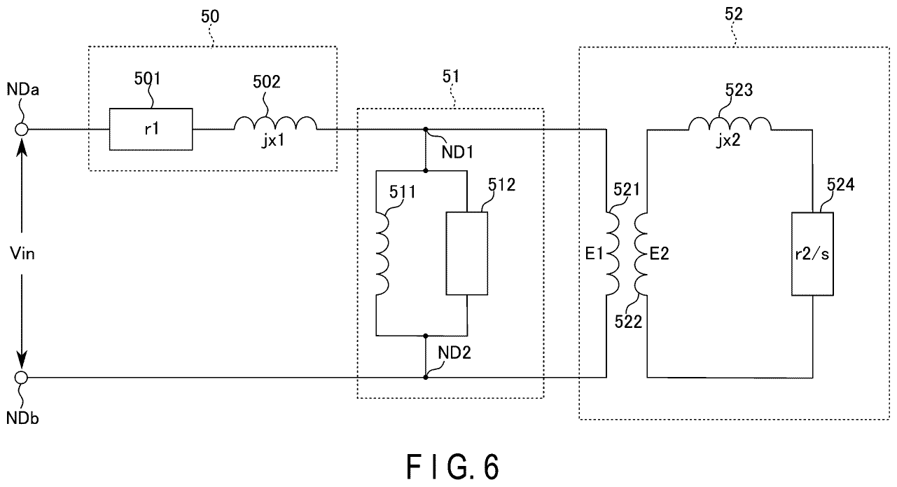

With reference to FIGS. 6, 7, and 8, a control device and an electric apparatus according to the second embodiment will be described.

In the above-described embodiment, an example has been described in which the outflow component of the electric signal changes due to a mechanical vibration in an induction motor. In this embodiment, an example will be described in which the outflow component changes due to a failure and a deterioration on a stator side.

As has been described above, in an electric apparatus 1 according to this embodiment, a failure sensing unit 320 of a control device 30 monitors the ratio of the outflow components to the RMS value. With this, in the electric apparatus 1 according to this embodiment, the control device 30 senses a failure of a motor 11.

FIG. 6 is a circuit diagram showing a circuit model of one phase of an induction motor (motor).

The motor 11 includes a stator 50, an excitation circuit 51, and a rotor 52.

The stator 50 includes a resistance component 501 and an inductive reactance component 502 of a winding. The resistance component 501 and the inductive reactance component 502 have a series connection relationship between an input node NDa and a node ND1. The resistance component 501 has a resistance value of “r1”. The inductive reactance component 502 has a reactance value of “j×1”.

The excitation circuit 51 includes an inductive reactance component 511 and a resistance component 512. The inductive reactance component 511 and the resistance component 512 have a parallel connection relationship between the node ND1 and a node ND2. The node ND2 is connected to an input node NDb.

The rotor 52 is connected to the nodes ND1 and ND2. The rotor 52 includes an inductive reactance component 521, an inductive reactance component 522, an inductive reactance component 523, and a resistance component 524 of windings.

The inductive reactance component 521 is located between the node ND1 and the node ND2. The inductive reactance component 522 is electromagnetically coupled to the inductive reactance component 521. The inductive reactance components 522 and 523 and the resistance component 524 have a series connection relationship.

The inductive reactance components 521 and 522 have a mutual inductance generated between the inductive reactance component 521 and the inductive reactance component 522. The inductive reactance component 521 generates an excitation voltage of “E1”. The inductive reactance component 522 generates an induced voltage of “E2”. The inductive reactance component 523 has a reactance value of “j×2”. The resistance component 524 has a resistance value of “r2/s”. “s” indicates a slip.

The stator 50, the excitation circuit 51, and the rotor 52 are driven by a drive voltage Vin applied between the nodes NDa and NDb.

In the circuit model shown in FIG. 6, the inductive load changes due to occurrence of a failure of the induction motor.

In FIG. 6, the state on the rotor 52 side changes in accordance of a change in the mutual inductance generated between the inductive reactance components 521 and 522 caused by a mechanical vibration. Thus, the inductive fluctuation appears in the current signal.

On the stator 50 side, if a short circuit or partial discharge occurs, the magnitude of the resistance component or the magnitude of the inductive reactance component of the winding changes. With this, a change in current caused by the inductive fluctuation appears.

These changes in current are detected as changes of the outflow components of the electric signal.

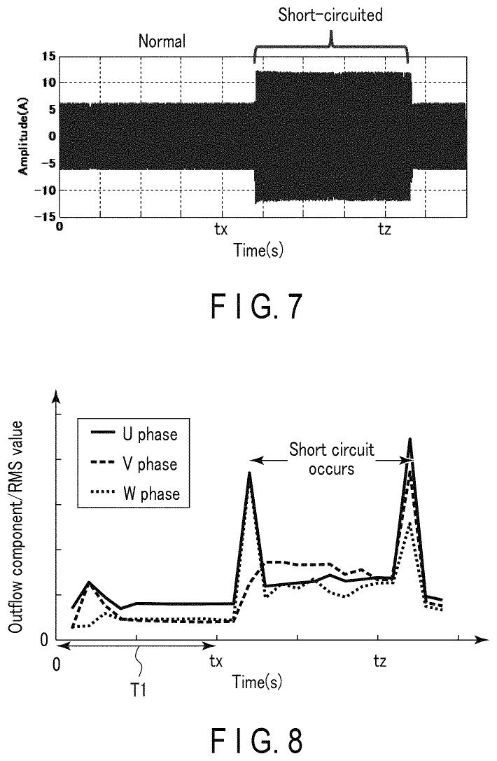

FIG. 7 shows the change in motor current in a case of occurrence of a short circuit in the winding of the stator 50. In FIG. 7, the abscissa of the graph corresponds to the time (sec) from the start of measurement, and the ordinate of the graph corresponds to the amplitude value of the motor current.

In FIG. 7, at time tx, the winding is forcibly (intentionally) short-circuited. As shown in FIG. 7, if a short circuit occurs in the winding, the value of the motor current increases after time tx.

At time tz, the short circuit in the winding is eliminated. With this, the value of the motor current decreases after time tz.

In this manner, in accordance with the presence/absence of a short circuit in the winding, the amplitude value of the motor current fluctuates.

FIG. 8 shows the result of frequency analysis concerning data of the motor current per a certain unit time under the condition shown in FIG. 7. FIG. 8 shows the comparison result of the ratios of the outflow components to the RMS value (RMS value/outflow component).

In FIG. 8, the abscissa of the graph corresponds to the time (sec), and the ordinate of the graph corresponds to the ratio of the outflow components to the RMS value. FIG. 8 shows the ratio of the outflow components to the RMS value in each of the U phase, V phase, and W phase.

In the embodiment, the failure sensing unit 320 continuously monitors the inflow signal, the outflow signal, and the ratio of the outflow components to the RMS value. The failure sensing unit 320 monitors the various values in time series for each unit time. Based on the frequencies of changes of various values, the failure sensing unit 320 grasps the state of the power supply 10 and the state of the motor 11.

In FIG. 8, in a period T1 from the start of measurement to about time tx, the induction motor is kept in a normal state. In the period T1, the value of the ratio of the outflow components to the RMS value is low.

As shown in FIG. 7 described above, a large change of the waveform of the motor current appears immediately after occurrence of a short circuit in the induction motor at given time tx.

Hence, as shown in FIG. 8, the change of the ratio of the outflow components to the RMS value is also large.

In the period from time tx to time tz, a current imbalance occurs in the state in which the short circuit constantly occurs in the induction motor. The ratio of the outflow components to the RMS value in this short circuit state is higher than the ratio of the outflow components to the RMS value in the current normal state.

At time tz, if the short circuit in the induction motor is eliminated, and the induction motor returns to the normal state, the current waveform largely changes. As a result, immediately after time tz, the ratio of the outflow components to the RMS value increases.

From the results of changes described above, in the winding of the stator 50 of the motor, if the wiring is partially short-circuited and partial discharge occurs due to defective insulation, the inductance changes. As a result, the outflow component of the current largely changes.

Therefore, by observing the ratio of the outflow components to the RMS value, the failure sensing unit 320 can sensitively detect the occurrence of partial discharge in the stator 50.

Also in a case where a short circuit continuously occurs in the winding, since the current waveform changes due to occurrence of current imbalance, the ratio of the outflow components to the RMS value becomes higher than normal.

As has been described above, the electric apparatus 1 according to this embodiment can sense the presence/absence of a short circuit in the induction motor by constantly monitoring the ratio of the outflow components to the RMS value. As a result, the electric apparatus 1 according to this embodiment can accurately grasp the deterioration state caused by partial discharge and an impact intermittently occurring in the electric apparatus 1.

Hence, the electric apparatus 1 according to this embodiment can implement a stable operation of the electric apparatus.

### (3) Third Embodiment

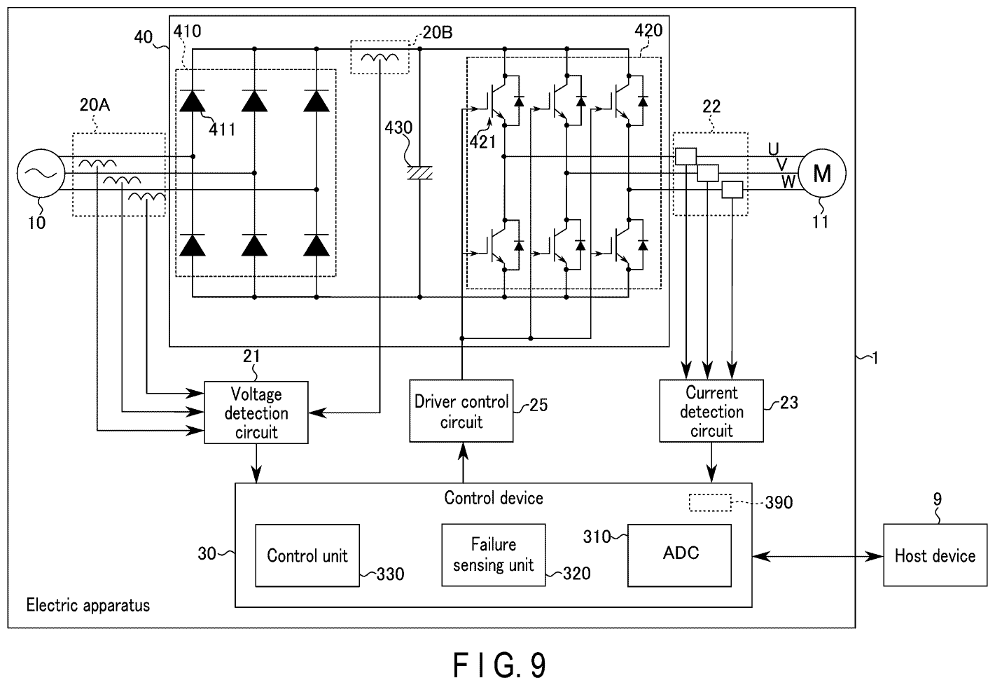

With reference to FIG. 9, a control device and an electric apparatus according to the third embodiment will be described.

FIG. 9 is a circuit diagram showing an arrangement example of an electric apparatus 1 according to this embodiment.

As shown in FIG. 9, the electric apparatus 1 according to this embodiment includes a power conversion device 40. The electric apparatus 1 according to this embodiment grasps the failure state of an electric motor by the arrangement shown in FIG. 9.

The power conversion device 40 drives a motor 11 by converting a power from an AC power supply 10. The power conversion device 40 includes a rectifying circuit 410, a switching circuit 420, and a smoothing capacitor 430.

The rectifying circuit 410 rectifies the supplied AC voltage. The rectifying circuit 410 outputs the rectified voltage (DC voltage). The rectifying circuit 410 includes a plurality of diodes 411. Two diodes 411 are connected in series between the high-potential side node and the low-potential side node of the power conversion device 40. The two diodes 411 connected in series form a leg. A plurality of legs are connected in parallel to each other. The rectifying circuit 410 includes three legs so as to correspond to the U phase, V phase, and W phase of the AC power supply 10.

The smoothing capacitor 430 smooths the voltage ripple (DC voltage) output from the rectifying circuit 410. The smoothing capacitor 430 is connected in parallel to the rectifying circuit 410 and the switching circuit 420 between the high-potential side node and the low-potential side node of the power conversion device 40.

The switching circuit 420 converts the supplied DC voltage into an AC voltage. The switching circuit 420 includes a plurality of switching elements 421. Each switching element 421 includes an IGBT (Insulated gate bipolar transistor) and a diode. Two switching elements 421 are connected in series between the high-potential side node and the low-potential side node of the power conversion apparatus 40. The two switching elements 421 connected in series form a leg. A plurality of legs are connected in parallel to each other. The switching circuit 420 includes three legs so as to correspond to the U phase, V phase, and W phase of the motor 11.

The power conversion device 40 can include other constituent elements such as an DC reactor (not shown).

The AC power supply 10 is connected to the rectifying circuit 410 of the power conversion device 40. Each phase wiring of the AC power supply 10 is connected to corresponding one of three legs of the rectifying circuit 410.

The motor 11 is connected to the switching circuit 420 of the power conversion device 40. Each phase wiring of the motor 11 is connected to corresponding one of three legs of the switching circuit 420.

A voltage sensor circuit 20A senses the state of the voltage signal of each phase of the AC power supply 10. The voltage sensor circuit 20A monitors the input power supply voltage.

A voltage sensor circuit 20B senses the state of the DC voltage output from the rectifying circuit 410. The voltage sensor circuit 20B monitors the rectified DC voltage.

A voltage detection circuit 21 transmits, to a control device 30, voltage signals indicating the sense results of the voltage sensor circuits 20A and 20B. Each voltage signal is an analog signal.

A current sensor circuit 22 senses the drive current output from the switching circuit 420. The current sensor circuit 22 monitors the drive current value to be supplied to the motor 11.

A current detection circuit 23 transmits, to the control device 30, a current signal indicating the sense result of the current sensor circuit 22. The current signal is an analog signal.

A driver control circuit 25 generates a PWM (pulse width modulation) signal or a PAM (pulse amplitude modulation) signal in accordance with an instruction from the control device 30. The driver control circuit 25 transmits the PWM signal or PAM signal to each switching element 421 of the switching circuit 420. Thus, the driver control circuit 25 drives the switching element 421 of the switching circuit 420. The driver control circuit 25 is connected to the gate (control terminal) of each switching element 421.

The control device 30 converts the analog signals transmitted from the voltage detection circuit 21 and the current detection circuit 23 into digital signals by an ADC 310. The obtained digital signals are used to control the power conversion device 40.

In accordance with a command from a host device 9, the control device 30 generates a command signal for controlling the rotation state of the motor 11. The control device 30 transmits the generated command signal to the driver control circuit 25. Thus, the control device 30 controls the operation of the motor 11 via the driver control circuit 25.

In this embodiment, a failure sensing unit 320 of the control device 30 acquires the digital signals corresponding to the sense results of the voltage sensor circuits 20A and 20B, and the digital signal corresponding to the sense result of the current sensor circuit 22. Thus, the failure sensing unit 320 constantly monitors the state of the power conversion device 40 and the state of the motor 11.

For example, the signal obtained from the voltage sensor circuit 20B includes a ripple voltage generated by the rectifying circuit 410. The ripple voltage appears as the second, fourth, or sixth harmonic with respect to the power supply frequency.

In this embodiment, a signal (ripple signal) concerning the ripple voltage included in the DC voltage is used as the fundamental frequency (fundamental wave), and the phase difference between the phase of the fundamental wave of the voltage signal and the phase of the current signal is compared. With this, in the electric apparatus 1 according to this embodiment, the failure sensing unit 320 of the control device 30 can identify an outflow signal and an inflow signal.

In general, if the switching circuit 420, the smoothing capacitor 430, or the DC reactor (not shown) is operating properly, the outflow component of the electric signal does not become large in frequency analysis of the voltage signal.

However, if a failure of a circuit component occurs, a change of the outflow component in the electric signal is observed as an inductive load fluctuation. Therefore, the failure sensing unit 320 can sense occurrence of the failure of the circuit component by analyzing the outflow component of the electric signal.

In the signal obtained from the current sensor circuit 22, when driving the motor 11, a signal component of the drive frequency is the main component of the signal concerning the current. However, the signal concerning the current includes, as a signal component, a harmonic, switching noise, or the like from the switching circuit 420.

In a case of sensing a failure of a bearing by motor current analysis, a sideband wave shifted from the drive frequency as a center by a rotational frequency is observed.

The switching noise to be observed occurs in synchronization with the drive frequency. Accordingly, the switching noise can be sensed as an inflow component which is substantially in-phase with the phase of the drive frequency. Since the phase of the sideband signal generated by the mechanical vibration of the motor 11 is different from the phase of the drive frequency, the signal due to the sideband wave can be sensed as an outflow component.

With the operations described above, in this embodiment, the control device 30 can cause the failure sensing unit 320 to isolate the noise derived from the power conversion device 40, thereby clearly sensing the failure state of the motor 11.

If the signal obtained from the voltage sensor circuit 20A or the voltage sensor circuit 20B is considered as an inflow component which is in-phase with the power supply frequency, the states of a malfunction and a failure on the AC power supply 10 side can be monitored. That is, the inflow component isolated by frequency analysis of the voltage signal represents the signal state on the AC power supply 10 side.

According to this, the control device 30 can sense external noise, a harmonic, and occurrence of a failure such as partial discharge or a short circuit in the electric wiring.

Hence, in the electric apparatus 1 according to this embodiment, the control device 30 including the failure sensing unit 320 can identify failures on the motor 11 side and the power conversion apparatus 40 side, and a malfunction caused by failures in the system on the power supply 10 side and power transmission side.

As has been described above, the electric apparatus 1 according to this embodiment can implement a stable operation of the electric apparatus.

In the control device 30 of the electric apparatus 1 according to this embodiment, the failure sensing unit 320 calculates and analyzes the inflow component signal and the outflow component signal. Thus, the failure sensing unit 320 senses the state of a failure occurring in the electric apparatus 1.

### (4) Modification

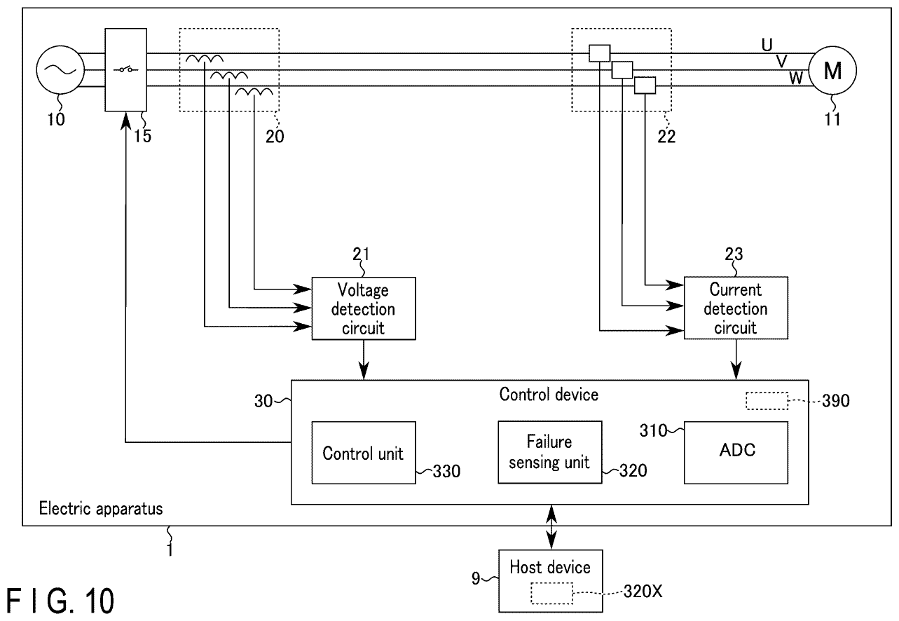

With reference to FIG. 10, a modification of the electric apparatus according to the embodiment will be described.

FIG. 10 is a circuit diagram showing a modification of the electric apparatus 1 according to the embodiment.

In the above-described embodiment, in place of the failure sensing unit 320 (and the control device 30), the host device 9 may execute calculation and analysis of the inflow component signal and the outflow component signal to grasp the failure state.

That is, the failure sensing unit 320 in the electric apparatus 1 has a function only for communicating, in the electric apparatus 1, various electric signals to the host device 9.

As shown in FIG. 10, the host device 9 includes a failure sensing unit 320X. The host device 9 executes, by the failure sensing unit 320X, frequency analysis, phase angle and amplitude calculation, comparison of the phase difference between the fundamental wave and the electric signal, extraction of an inflow component, and extraction of an outflow component based on signals from the failure sensing unit 320 of the electric apparatus 1.

With this arrangement, the host device 9 grasps the failure state in the electric apparatus 1 from outside the electric apparatus 1. Hence, the host device 9 functions as the control device of the motor 11 and the electric apparatus 1.

In the host device 9, various functions implemented by the failure sensing unit 320 as shown in FIG. 2 are operated by implementation by software as algorisms and analysis methods.

With this, in a system (network) including the electric apparatus 1 and the host device 9, the calculation load on the edge-side device (electric apparatus 1) is reduced.

If the above-described sensing of a failure of the electric apparatus based on the outflow component and the inflow component is applied to an existing system, the host device 9 capable of failure sensing in this embodiment can operate the entire system with high scalability without adding the failure sensing unit 320 to an existing electric apparatus, as in this modification.

As has been described above, this modification enables a stable operation of the system including the electric apparatus 1.

### (5) Others

The electric apparatus 1 and the control device 30 in the above-described embodiment are applicable to a railroad car, an industrial plant, a conveyance system, or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The functionality of the elements disclosed herein may be implemented using circuitry or processing circuitry which includes general purpose processors, special purpose processors, integrated circuits, ASICs (“Application Specific Integrated Circuits”), FPGAS (“Field Programmable Gate Arrays”), conventional circuitry and/or combinations thereof which are programmed, using one or more programs stored in one or more memories, or otherwise configured to perform the disclosed functionality. Processors are considered processing circuitry or circuitry as they include transistors and other circuitry therein. The processor may be a programmed processor which executes a program stored in a memory. In the disclosure, the circuitry, units, or means are hardware that carry out or are programmed to perform the recited functionality. The hardware may be any hardware disclosed herein which is programmed or configured to carry out the recited functionality.

What is claimed is:

1. A control device comprising:
a control circuitry configured to control an electric motor; and
a failure sensing circuitry configured to sense a failure of the electric motor,
wherein the failure sensing circuitry
executes frequency analysis concerning an electric signal for driving the electric motor,
calculates a phase of the electric signal,
calculates a phase difference between a phase of a fundamental wave of a power supply frequency of the electric signal and the calculated phase of the electric signal,
extracts a first signal indicating an outflow component from the electric motor based on a calculation result of the phase difference,
extracts a second signal indicating an inflow component to the electric motor based on the calculation result of the phase difference, and
senses the failure based on the first signal.

2. The device according to claim 1, wherein
the inflow component is a component where a phase difference between a phase of a fundamental wave of a voltage signal included in the electric signal and the calculated phase of a current signal included in the electric signal has a value within one of a range of 0° to +90° and a range of 0° to −90°, and
the outflow component is a component where the phase difference between the phase of the fundamental wave of the voltage signal and the phase of the current signal has a value within one of a range of +90° to +180° and a range of −90° to −180°.

3. The device according to claim 1, wherein
the failure sensing circuitry
compares the first signal with a third signal indicating a normal state of the electric motor, and
monitors a state of the electric motor based on a result of comparison between the first signal and the third signal.

4. The device according to claim 1, wherein
the failure sensing circuitry
compares the second signal with a third signal indicating a normal state of the electric motor, and
monitors a state of a power supply based on a result of comparison between the second signal and the third signal.

5. The device according to claim 1, wherein
the failure sensing circuitry
calculates an amplitude of the electric signal, and
monitors a state of the electric motor based on a first ratio of a first value indicating a spectrum total sum obtained by the frequency analysis and a second value indicating a total sum of amplitudes of the first signals.

6. The device according to claim 5, wherein
the failure sensing circuitry
monitors the first ratio, and
monitors the state of the electric motor based on a frequency of a change of the first ratio in a certain period.

7. The device according to claim 1, wherein
the failure sensing circuitry
monitors a DC voltage in a power conversion device configured to drive the electric motor,
calculates, while using a ripple signal included in the DC voltage as the fundamental wave, the phase difference between the phase of the fundamental wave of the electric signal and the calculated phase of the electric signal, and
extracts the first signal and the second signal based on a calculation result of the phase difference.

8. The device according to claim 7, wherein
the failure sensing circuitry monitors a state of the power conversion device based on a change in the first signal obtained from a monitor result of the DC voltage.

9. The device according to claim 7, wherein
the failure sensing circuitry monitors a state of a power supply based on a change in the second signal obtained from a monitor result of the DC voltage.

10. An electric apparatus comprising:
an electric motor connected a power supply; and
a control device defined in claim 1, configured to control the electric motor and sense a failure of the electric motor.

11. A control method of an electric apparatus, the method comprising:
executing frequency analysis concerning an electric signal for driving an electric motor;
calculating a phase of the electric signal,
calculating a phase difference between a phase of a fundamental wave of a power supply frequency of the electric signal and the calculated phase of the electric signal,
extracting a first signal indicating an outflow component from the electric motor based on a calculation result of the phase difference, and
sensing a failure based on the first signal.

12. The method according to claim 11, further comprising:
extracting a second signal indicating an inflow component to the electric motor based on the calculation result of the phase difference.

13. The method according to claim 12, wherein
the inflow component is a component where a phase difference between a phase of a fundamental wave of a voltage signal included in the electric signal and the calculated phase of a current signal included in the electric signal has a value within one of a range of 0° to +90° and a range of 0° to −90°, and
the outflow component is a component where the phase difference between the phase of the fundamental wave of the voltage signal and the phase of the current signal has a value within one of a range of +90° to +180° and a range of −90° to −180°.

14. The method according to claim 12, wherein
a DC voltage in a power conversion device configured to drive the electric motor is monitored,
the phase difference between the phase of the fundamental wave of the electric signal and the calculated phase of the electric signal is calculated while using a ripple signal included in the DC voltage as the fundamental wave, and
the first signal and the second signal are extracted based on a calculation result of the phase difference.

15. The method according to claim 14, wherein
a state of the power conversion device is monitored based on a change in the first signal obtained from a monitor result of the DC voltage.

16. The method according to claim 14, wherein
a state of a power supply is monitored based on a change in the second signal obtained from a monitor result of the DC voltage.

17. The method according to claim 12, wherein
the second signal is compared with a third signal indicating a normal state of the electric motor, and
a state of a power supply is monitored based on a result of comparison between the second signal and the third signal.

18. The method according to claim 11, wherein
the first signal is compared with a third signal indicating a normal state of the electric motor, and
a state of the electric motor is monitored based on a result of comparison between the first signal and the third signal.

19. The method according to claim 11, wherein
an amplitude of the electric signal is calculated, and
a state of the electric motor is monitored based on a first ratio of a first value indicating a spectrum total sum obtained by the frequency analysis and a second value indicating a total sum of amplitudes of the first signals.

20. The method according to claim 19, wherein
the first ratio is monitored, and
the state of the electric motor is monitored based on a frequency of a change of the first ratio in a certain period.
